(19) United States
(12) Patent Application Publication
(10) Pub. No.: US 2016/0149000 A1
(43) Pub. Date: May 26, 2016

(54) SEMICONDUCTOR WAFER AND METHOD OF PRODUCING SEMICONDUCTOR WAFER

(71) Applicant: SUMITOMO CHEMICAL COMPANY, LIMITED, Tokyo (JP)

(72) Inventor: Hiroyuki SAZAWA, Tsukuba-shi (JP)

(73) Assignee: SUMITOMO CHEMICAL COMPANY, LIMITED, Tokyo (JP)

(21) Appl. No.: 15/008,974

(22) Filed: Jan. 28, 2016

Related U.S. Application Data
(63) Continuation-in-part of application No. PCT/JP2014/003974, filed on Jul. 29, 2014.

(30) Foreign Application Priority Data
Jul. 30, 2013 (JP) 2013-158365

(51) Int. Cl. H01L 29/06; H01L 29/20; H01L 29/207; H01L 29/15

(52) U.S. Cl. CPC H01L 29/0684; H01L 29/155; H01L 29/2003; H01L 29/0607; H01L 29/207

(57) ABSTRACT

A semiconductor wafer includes first and second superlattice layers. The first superlattice layer includes first unit layers each of which includes first and second layers, the second superlattice layer includes second unit layers each of which includes third and fourth layers, the first layer is made of Alₓ₁Ga₁₋ₓ₁N (0<x1≦1), the second layer is made of Al_{y1}Ga_{1-y1}N (0≦y1<1, x1>y1), the third layer is made of Alₓ₂Ga₁₋ₓ₂N (0<x2≦1), the fourth layer is made of Al_{y2}Ga_{1-y2}N (0≦y2<1, x2>y2), an average lattice constant of the first superlattice layer is different from that of the second superlattice layer, and one or more layers selected from the first and second superlattice layers contain impurity atoms that improve a breakdown voltage and that have a concentration higher than 7×10¹⁸ [atoms/cm³].

The contents of the following Japanese patent applications are incorporated herein by reference:

NO. 2013-158365 filed on Jul. 30, 2013, and

NO. PCT/JP2014/003974 filed on Jul. 29, 2014.

### BACKGROUND

1. Technial Field

The present invention relates to a semiconductor wafer and a method of producing a semiconductor wafer.

2. Related Art

Techniques are desired to form high-quality nitride semiconductor crystal layers on silicon wafers for the purpose of using them for high-breakdown-voltage devices. The document “High quality GaN grown on Si(111) by gas source molecular beam epitaxy with ammonia”, S. A. Nikishin et. al., Applied Physics letter, Vol. 75, 2073(1999)” discloses a structure in which a buffer layer, a superlattice structure and a gallium nitride layer are stacked in the stated order on the silicon (111) plane. Here, the gallium nitride layer provides an active layer of a transistor. This structure can achieve reduced warpage of the wafer due to the presence of the superlattice structure, and is thus advantageous in that a relatively thick gallium nitride layer can be easily formed and a nitride semiconductor crystal layer having a high breakdown voltage can be easily obtained. When the nitride semiconductor crystal layer is thickened to increase the breakdown voltage, however, the warpage of the wafer increases and may exceed the permissible range of warpage for the device fabrication step. The techniques disclosed in Japanese Patent Application Publication No. 2011-238685 and International Publication No. WO 2011/102045 are known to control the amount of warpage of the wafer.

According to the technique disclosed in Japanese Patent Application Publication No. 2011-238685, a first GaN/AlN superlattice layer is formed on a wafer. In the first GaN/AlN superlattice layer, a plurality of pairs of a GaN layer and an AlN layer are stacked in such a manner that the GaN layers and the AlN layers are alternately stacked. In addition, a second GaN/AlN superlattice layer is formed and in contact with the first GaN/AlN superlattice layer. In the second GaN/AlN superlattice layer, a plurality of pairs of a GaN layer and an AlN layer are stacked in such a manner that the GaN layers and the AlN layers are alternately stacked. On the second GaN/AlN superlattice layer, a device operating layer made up by a GaN electron transit layer and an AlGaN electron supplying layer is formed. Here, Japanese Patent Application Publication No. 2011-238685 discloses that the relation of LC1<LC2<LC3 is satisfied, where LC1 denotes the c-axis average lattice constant of the first GaN/AlN superlattice layer, LC2 the c-axis average lattice constant of the second GaN/AlN superlattice layer, and LC3 the c-axis average lattice constant of the GaN electron transit layer.

International Publication No. WO 2011/102045 discloses an epitaxial wafer in which a set of Group III nitride layers is formed on the (111) monocrystalline Si wafer in such a manner that the (0001) crystal plane is substantially parallel to the surface of the wafer. The epitaxial wafer includes a buffer layer and a crystal layer formed on the buffer layer, and the buffer layer is formed by alternately stacking first units of stacking and second units of stacking in such a manner that the top and bottom portions are both formed by the first units of stacking. The first unit of stacking includes a composition changing layer and a first intermediate layer. In the composition changing layer, first unit layers and second unit layers having different compositions are repeatedly and alternately stacked to contain compressive strain therein. The first intermediate layer enhances the compressive strain contained in the composition changing layer. The second unit of stacking is formed as a second intermediate layer having substantially no strain.

For the purpose of achieving a high-breakdown-voltage nitride semiconductor crystal layer, the present inventors have conducted experiments and reviewed the results to introduce impurity atoms such as carbon atoms into an underlying layer (a superlattice layer) of the nitride semiconductor crystal layer. The present inventors have acknowledged the above-mentioned approach of simply introducing impurity atoms has a problem. Specifically speaking, the stress within the superlattice layer, which is provided to control the amount of warpage of the wafer, is relaxed and its effect of controlling the amount of warpage of the wafer is undermined. In other words, the present inventors have concluded as follows. The techniques disclosed in the above-mentioned Japanese Patent Application Publication No. 2011-238685 and International Publication No. WO 2011/102045 to control the amount of warpage of the wafer can only be used when no impurity atoms have been introduced to improve the breakdown voltage or when only a small amount of impurity atoms have been introduced. The techniques disclosed in Japanese Patent Application Publication No. 2011-238685 and International Publication No. WO 2011/102045 can no longer control the amount of warpage of the wafer once impurity atoms have been introduced to such an extent that the breakdown voltage is sufficiently improved.

The objects of the present invention are to provide a semiconductor wafer having such a layer structure that the superlattice layer, which serves as an underlying layer of the nitride semiconductor crystal layer, maintains its effects of controlling the amount of warpage of the wafer even if the superlattice layer has been doped with such an amount of impurity atoms that the breakdown voltage is effectively and sufficiently improved, and to provide a method of producing the semiconductor wafer.

### SUMMARY

In order to achieve the above-mentioned objects, a first embodiment of the present invention is to provide a semiconductor wafer comprising an underlying wafer, a first superlattice layer, a connection layer, a second superlattice layer and a nitride semiconductor crystal layer. Here, the underlying wafer, the first superlattice layer, the connection layer, the second superlattice layer and the nitride semiconductor crystal layer are positioned in an order of the underlying wafer, the first superlattice layer, the connection layer, the second superlattice layer and the nitride semiconductor crystal layer, the first superlattice layer includes a plurality of first unit layers each of which is made up by a first layer and a second layer, the second superlattice layer includes a plurality of second unit layers each of which is made up by a third layer and a fourth layer, the first layer is made of Alₓ₁Ga₁₋ₓ₁N (0<x1≦1), the second layer is made of Al_{y1}Ga_{1-y1}N (0≦y1<1, x1>y1), the third layer is made of Alₓ₂Ga₁₋ₓ₂N (0<x2≦1), the fourth layer is made of Al_{y2}Ga_{1-y2}N (0≦y2<1, x2>y2), an average lattice constant of the first superlattice layer is different from an average lattice constant of the second superlattice layer, one or more layers selected from the first superlattice layer and the second superlattice layer contain impurity atoms that improve a breakdown voltage and that have a concentration higher than 7×10¹⁸ [atoms/cm³].

The impurity atoms can be one or more species selected from the group consist of C atoms, Fe atoms, Mn atoms, Mg atoms, V atoms, Cr atoms, Be atoms and B atoms. The impurity atoms are preferably C atoms or Fe atoms. The connection layer is preferably a crystal layer in contact with the first superlattice layer and the second superlattice layer. A composition of the connection layer may change in a continuous manner in a thickness direction of the connection layer from the first superlattice layer to the second superlattice layer. Alternatively, a composition of the connection layer may change in a stepwise manner in a thickness direction of the connection layer from the first superlattice layer to the second superlattice layer. The connection layer can be made of Al_{z}Ga_{1-z}N (0≦z≦1). A thickness of the connection layer is preferably larger than a thickness of any of the first layer, the second layer, the third layer and the fourth layer. An average lattice constant of the connection layer is preferably smaller than an average lattice constant of any of the first superlattice layer and the second superlattice layer.

A second embodiment of the present invention is to provide a method of producing the semiconductor wafer of the first embodiment. The production method includes forming the first superlattice layer by forming the first unit layer, which is made up by the first layer and the second layer, n times, forming the connection layer, forming the second superlattice layer by forming the second unit layer, which is made up by the third layer and the fourth layer, m times, and forming the nitride semiconductor crystal layer. Here, during one or more formations selected from the formation of the first superlattice layer and the formation of the second superlattice layer, the one or more of the first superlattice layer and the second superlattice layer are formed so as to contain impurity atoms that improve a breakdown voltage of the one or more of the first superlattice layer and the second superlattice layer and that have a concentration higher than 7×10¹⁸ [atoms/cm³].

Depending on a composition and a thickness of the nitride semiconductor crystal layer, one or more parameters selected from (i) a composition of each of the first to fourth layers, (ii) a thickness of each of the first to fourth layers, (iii) the number n of the unit layers included in the first superlattice layer and (iv) the number m of the unit layers included in the second superlattice layer can be adjusted so that warpage of the semiconductor wafer measured at a surface of the nitride semiconductor crystal layer is 50 μm or less. Depending on the composition and the thickness of the nitride semiconductor crystal layer, the number n of the unit layers included in the first superlattice layer and the number m of the unit layers included in the second superlattice layer are preferably adjusted so that the warpage of the semiconductor wafer measured at the surface of the nitride semiconductor crystal layer is 50 μm or less.

### BRIEF DESCRIPTION OF THE DRAWINGS

FIG. 1 is a cross-sectional view of a semiconductor wafer 100.

FIG. 2 is a graph showing the amount of warpage and the breakdown voltage in relation to the carbon atom concentration for semiconductor wafers of a first implementation.

FIG. 3 is a graph showing the amount of warpage and the breakdown voltage in relation to the carbon atom concentration for semiconductor wafers of a first comparative example.

FIG. 4 is a graph showing the amount of warpage and the breakdown voltage in relation to the carbon atom concentration for semiconductor wafers of a second comparative example.

FIG. 5 is a graph showing the amount of warpage and the breakdown voltage in relation to the carbon atom concentration for semiconductor wafers of a third comparative example.

FIG. 6 is a graph showing the amount of warpage and the breakdown voltage in relation to the carbon atom concentration for semiconductor wafers of a second implementation.

FIG. 7 is a graph showing the amount of warpage in relation to the carbon atom concentration for the semiconductor wafers of the first and second implementations and the first to third comparative examples.

FIG. 8 is a graph showing the amount of warpage and the breakdown voltage for semiconductor wafers of a third implementation in which the numbers of the unit layers of first and second superlattice layers are set at various values.

FIG. 9 is a graph showing the amount of warpage for semiconductor wafers of a fourth implementation in which the numbers of the unit layers of first and second superlattice layers are set at various values.

FIG. 10 is a graph showing the amount of warpage in relation to the difference in average lattice constant for semiconductor wafers of a fifth implementation.

### DESCRIPTION OF EXEMPLARY EMBODIMENTS

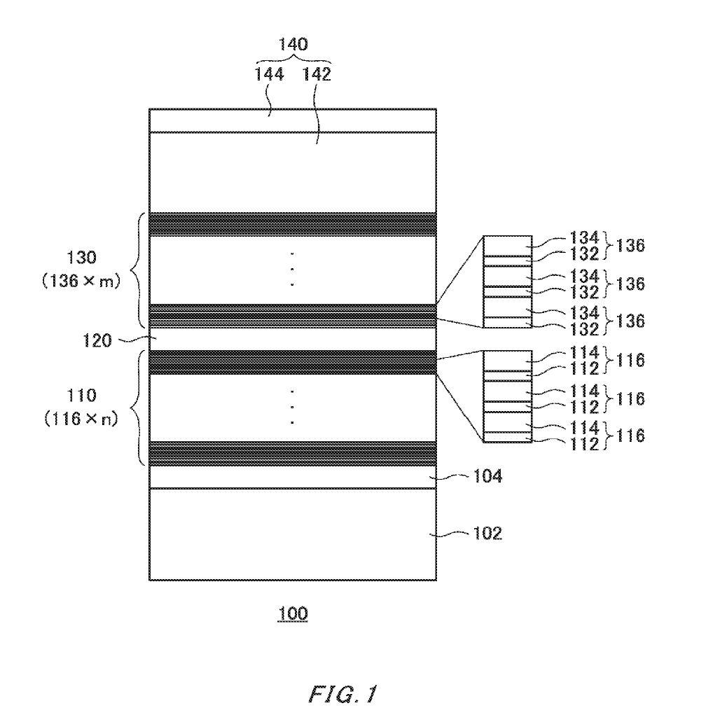

FIG. 1 is a cross-sectional view of a semiconductor wafer 100 according to an embodiment of the present invention. The semiconductor wafer 100 includes an underlying wafer 102, a buffering layer 104, a first superlattice layer 110, a connection layer 120, a second superlattice layer 130 and a nitride semiconductor crystal layer 140. The underlying wafer 102, the first superlattice layer 110, the connection layer 120, the second superlattice layer 130 and the nitride semiconductor crystal layer 140 are disposed in the order of the underlying wafer 102, the first superlattice layer 110, the connection layer 120, the second superlattice layer 130 and the nitride semiconductor crystal layer 140.

The underlying wafer 102 is a substrate to support the buffering layer 104 and the respective layers positioned thereon, which will be described later. The underlying wafer 102 can be made of any materials as long as the underlying wafer 102 has mechanical strength necessary to support the individual layers and thermal stability to allow the individual layers to be formed by epitaxial growth and other techniques. The underlying wafer 102 can be, for example, a Si wafer, a sapphire wafer, a Ge wafer, a GaAs wafer, an InP wafer or a ZnO wafer.

The buffering layer 104 is designed to absorb the difference in lattice constant between the underlying wafer 102 and the first superlattice layer 110. The buffering layer 104 can be formed by epitaxial growth with the reaction temperature (the temperature of the wafer) being set to 500° C. to 1000° C. When a Si(111) wafer is used as the underlying wafer 102 and an AlGaN-based material is used for the first superlattice layer 110, the buffering layer 104 can be, for example, an AlN layer. The buffering layer 104 preferably has a thickness of 10 nm to 300 nm, more preferably 50 nm to 200 nm.

The first superlattice layer 110, the connection layer 120 and the second superlattice layer 130 provide a layer structure that enables the amount of warpage of the semiconductor wafer 100 to be controlled even when a sufficient amount of impurity atoms have been introduced to improve the breakdown voltage. The first superlattice layer 110 has a plurality of first unit layers 116, and the second superlattice layer 130 has a plurality of second unit layers 136.

The first unit layer 116 is made up by a first layer 112 and a second layer 114, and the second unit layer 136 is made up by a third layer 132 and a fourth layer 134. The first layer 112 is made of Alₓ₁Ga₁₋ₓ₁N (0<x1≦1) and the second layer 114 is made of Al_{y1}Ga_{1-y1}N (0≦y1<1, x1>y1). The third layer 132 is made of Alₓ₂Ga₁₋ₓ₂N (0<x2≦1) and the fourth layer 134 is made of Al_{y2}Ga_{1-y2}N (0≦y2<1, x2>y2).

The first layer 112, the second layer 114, the third layer 132 and the fourth layer 134 can be formed by epitaxial growth. The first layer 112 and the third layer 132 can be, for example, an AlN layer, when x1 and x2 are set to 1. The first layer 112 and the third layer 132 preferably have a thickness of 1 nm to 10 nm, more preferably 3 nm to 7 nm. As for the second layer 114 and the fourth layer 134, y1 and y2 can be set within a range of 0.05 to 0.25. In other words, the second layer 114 and the fourth layer 134 can be Al_{0.05}Ga_{0.95}N to Al_{0.25}Ga_{0.75}N, for example. The second layer 114 and the fourth layer 134 preferably have a thickness within the range of 10 nm to 30 nm, more preferably 15 nm to 25 nm.

A plurality of first unit layers 116, each of which is made up by the first layer 112 and the second layer 114, construct the first superlattice layer 110. The average lattice constant a1 of the first superlattice layer 110 can be varied by varying the compositions (the A1 ratios) and the thicknesses of the first layers 112 and the second layers 114. The average lattice constant al of the first superlattice layer 110 can be defined as the result of the lattice constant of the first layers 112×the ratio of the first layers 112+the lattice constant of the second layers 114×the ratio of the second layers 114. The number n of the first unit layers 116 included in the first superlattice layer 110 preferably falls within the range of 1 to 200, more preferably 1 to 150.

A plurality of second unit layers 136, each of which is made up by the third layer 132 and the fourth layer 134, construct the second superlattice layer 130. The average lattice constant a2 of the second superlattice layer 130 can be varied by varying the compositions (the A1 ratios) and the thicknesses of the third layers 132 and the fourth layers 134. The average lattice constant a2 of the second superlattice layer 130 can be defined as the result of the lattice constant of the third layers 132×the ratio of the third layers 132+the lattice constant of the fourth layers 134×the ratio of the fourth layers 134. The number m of the second unit layers 136 included in the second superlattice layer 130 preferably falls within the range of 1 to 200, more preferably 1 to 150.

In the semiconductor wafer 100, the average lattice constant al of the first superlattice layer 110 is different from the average lattice constant a2 of the second superlattice layer 130, and one or more layers selected from the first superlattice layer 110 and the second superlattice layer 130 contain impurity atoms that are designed to improve the breakdown voltage and that have a concentration higher than 7×10¹⁸ [atoms/cm³]. The impurity atoms can be one or more pieces selected from the group consist of C atoms, Fe atoms, Mn atoms, Mg atoms, V atoms, Cr atoms, Be atoms and B atoms. The impurity atoms are preferably C atoms or Fe atoms, in particular, C atoms.

The connection layer 120 is configured to connect the first superlattice layer 110 and the second superlattice layer 130 to each other. The connection layer 120 can be formed by epitaxial growth. The connection layer 120 can be, for example, made of Al_{z}Ga_{1-z}N (0≦z≦1). The connection layer 120 can be a crystal layer in contact with the first superlattice layer 110 and the second superlattice layer 130. The connection layer 120 may be a single layer or multiple layers. In addition, the composition of the connection layer 120 may change in the thickness direction. Specifically speaking, the composition of the connection layer 120 may change in a continuous manner in the thickness direction of the connection layer 120 from the first superlattice layer 110 to the second superlattice layer 130. Alternatively, the composition of the connection layer 120 may change in a stepwise manner in the thickness direction of the connection layer 120 from the first superlattice layer 110 to the second superlattice layer 130. The thickness of the connection layer 120 can be set larger than the thickness of any of the first layer 112, the second layer 114, the third layer 132 and the fourth layer 134. The average lattice constant of the connection layer 120 can be set smaller than the average lattice constant of any of the first superlattice layer 110 and the second superlattice layer 130. The thickness of the connection layer 120 can be 20 to 300 nm, preferably 25 to 200 nm, more preferably 30 to 200 nm, particularly preferably 30 to 150 nm.

The nitride semiconductor crystal layer 140 can have a device base layer 142 and an active layer 144. An increase in the thickness of the device base layer 142 can result in a higher breakdown voltage of a device. In the active layer 144, an active region of a transistor, such as a channel, is formed.

According to the semiconductor wafer 100 of the present embodiment, a high breakdown voltage of 450 V or higher can be realized by introducing impurity atoms having a concentration higher than 7×10¹⁸ [atoms/cm³] and, at the same time, the amount of warpage measured at the surface of the nitride semiconductor crystal layer 140 can be reduced to 50 μm (the absolute value) or less. Here, the amount of warpage means the height of the center of the wafer with reference to the edge of the wafer and takes a negative value when the nitride semiconductor crystal layer 140 becomes convex and a positive value when the nitride semiconductor crystal layer 140 becomes concave.

As mentioned above, the amount of warpage of the semiconductor wafer 100 can be still controlled to be 50 μm or less (the absolute value) even when the introduced impurity atoms reach a concentration of 7×10¹⁸ [atoms/cm³], which can achieve a high breakdown voltage of 450 V or higher. This advantageous effect can be produced through the following mechanism.

When a GaN-based crystal layer is stacked on a Si wafer, the GaN-based crystal is grown in a lattice-matching manner on the Si wafer at a high temperature and warped in an upwardly concave manner after the temperature is lowered since the coefficient of thermal expansion of the GaN-based crystal is higher than the coefficient of thermal expansion of Si. When the GaN-based crystal layer is warped in an upwardly concave manner, the surface of the GaN-based crystal layer which is opposite to the Si wafer is concave. Here, a laminate of an upper superlattice (USL) layer and a lower superlattice (LSL) layer is provided between the Si wafer and the GaN layer. The average lattice constant a_{U} of the USL layer and the average lattice constant a_{L} of the LSL layer are configured such that the relation of a_{U}>a_{L} is satisfied. In this way, the stress resulting from the difference in average lattice constant between the USL layer and the LSL layer create compressive stress that acts in the USL layer and tensile stress that acts on the LSL layer. The stress that acts on the laminate made up by the USL layer and the LSL layer (may be referred herein to as the “USL/LSL structure”) causes warpage in an upwardly convex manner, which goes in the opposite direction to the above-mentioned warpage caused by the difference in thermal expansion coefficient. Accordingly, the USL/LSL structure can effectively reduce the warpage of the wafer.

Here, the stress acts on the USL/LSL structure with the fulcrum point being positioned in the vicinity of the interface between the USL layer and the LSL layer. It is believed that the fulcrum point has a width (a thickness in the growing direction) of approximately several to several dozen nanometers since, in reality, the crystal contains dislocations and uneven interfaces. If GaN crystal contains many impurity atoms such as carbon atoms, the GaN crystal is likely to generate defects in the vicinity of the interfaces between stacked layers. Therefore, if the USL/LSL structure contains many impurity atoms, many defects are believed to be generated at the interface between the USL layer and the LSL layer or at the superlattice interfaces within the USL layer and the LSL layer. If forces act on such interfaces having many defects, crystallization relaxation is believed to resultantly occur in the vicinity of the crystal interfaces. The crystallization relaxation absorbs the stress generated within the USL/LSL structure, and the stress generated in the USL/LSL structure no longer contributes to the upwardly convex warpage. In other words, the USL/LSL structure can no longer control the amount of warpage of the wafer. Accordingly, a semiconductor wafer containing many carbon atoms is only affected by the force resulting from the difference in thermal expansion coefficient between Si and GaN and consequently warped significantly in a downwardly convex manner.

To address this issue, the semiconductor wafer 100 relating to the present embodiment has the connection layer 120 between the first superlattice layer 110 (equivalent to the above-described LSL layer) and the second superlattice layer 130 (equivalent to the above-described USL layer). The connection layer 120 serves as the fulcrum point of the stress generated by the difference in average lattice constant between the first superlattice layer 110 and the second superlattice layer 130. The connection layer 120 is thicker than the first layer 112, the second layer 114, the third layer 132 and the fourth layer 134 that make up the first superlattice layer 110 and the second superlattice layer 130 and has a low density of interfaces per unit length in the growing direction (the thickness direction). Thus, the connection layer 120 is less likely to be affected by the relaxation at the interfaces. Accordingly, even if the first superlattice layer 110 or the second superlattice layer 130 contains many carbon atoms, the connection layer 120 allows the stress creased in the first superlattice layer 110 and the stress generated in the second superlattice layer 130 to be transferred mutually. That is to say, the amount of warpage can be controlled. Consequently, the warpage of the semiconductor wafer 100 can be reduced.

In addition, since the connection layer 120 is thicker than the first layer 112, the second layer 114, the third layer 132 and the fourth layer 134 that make up the first superlattice layer 110 and the second superlattice layer 130, the connection layer 120 also effectively reduces, during its growth, the defects such as dislocations generated at the interfaces. This is due to the fact that dislocations having oppositely signed Burgers vectors are combined with each other during growth. As a result, the connection layer 120 can contribute to reduce defects not only at the interfaces but also within the bulk crystals. Thus, it is believed that the connection layer 120 can allow the stress to be transferred more efficiently. For the above-described reasons, even if the first superlattice layer 110 or the second superlattice layer 130 contains a high concentration of carbon atoms, the warpage of the wafer can be reduced.

The above-described semiconductor wafer 100 can be produced by the following production method. The buffering layer 104 is formed on the underlying wafer 102. After this, the first unit layer 116 is formed n times to form the first superlattice layer 110. Here, the first unit layer 116 is made up by the first layer 112 and the second layer 114. Following this, the connection layer 120 is formed, and the second unit layer 136 is formed m times to form the second superlattice layer 130. Here, the second unit layer 136 is made up by the third layer 132 and the fourth layer 134. Furthermore, the nitride semiconductor crystal layer 140 can be formed. Here, during one or more formations selected from the formation of the first superlattice layer 110 and the formation of the second superlattice layer 130, the one or more of the layers 110 and 130 are formed in such a manner that the layers contain impurity atoms that improve the breakdown voltage of the layers and that have a concentration higher than 7×10¹⁸ [atoms/cm³].

The first layer 112, the second layer 114, the connection layer 120, the third layer 132, the fourth layer 134 and the nitride semiconductor crystal layer 140 can be formed by epitaxial growth. The epitaxial growth can be realized using, for example, MOCVD (Metal Organic Chemical Vapor Deposition) and MBE (Molecular Beam Epitaxy). When MOCVD is employed, the source gas can be trimethylgallium (TMG), trimethylaluminum (TMA) or NH₃ (ammonia). The carrier gas may be a nitrogen or hydrogen gas. The reaction temperature can be selected within the range of 400° C. to 1300° C.

When carbon atoms are used as the impurity atoms, the concentration of the carbon atoms can be controlled by regulating at least one of the ratio between the Group-III source gas and the Group-V source gas, the reaction temperature and the reaction pressure. Provided that the other conditions are the same, the concentration of the carbon atoms drops as the reaction temperature rises and rises as the ratio of the Group-V source gas to the Group-III source gas drops. Furthermore, the concentration of the carbon atoms ascends as the reaction pressure descends. The concentration of the carbon atoms can be detected by, for example, SIMS (secondary ion mass spectrometry).

Depending on the composition and the thickness of the nitride semiconductor crystal layer 140, one or more parameters selected from (i) the composition of each of the first to fourth layers 112 to 134, (ii) the thickness of each of the first to fourth layers 112 to 134, (iii) the number n of the unit layers included in the first superlattice layer 110 and (iv) the number m of the unit layers included in the second superlattice layer 130 can be adjusted so that the warpage of the semiconductor wafer 100 measured at the surface of the nitride semiconductor crystal layer 140 is 50 μm or less. Depending on the composition and the thickness of the nitride semiconductor crystal layer 140, the number n of the unit layers included in the first superlattice layer 110 and the number m of the unit layers included in the second superlattice layer 130 can be adjusted so that the warpage of the semiconductor wafer 100 measured at the surface of the nitride semiconductor crystal layer 140 is 50 μm or less.

(First Implementation)

A 4-inch Si wafer (having a thickness of 625 μm, p-doped) having the plane orientation (111) was used as the underlying wafer 102 and an AlN layer having a thickness of 150 nm was formed on the Si wafer as the buffering layer 104. On this AlN layer, an AlN layer having a thickness of 5 nm was formed as the first layer 112, and an Al_{0.15}Ga_{0.85}N layer having a thickness of 16 nm was formed as the second layer 114. The AlN layer having a thickness of 5 nm and the Al_{0.15}Ga_{0.85}N layer make up the first unit layer 116. Here, 75 first unit layers 116 were formed to provide the first superlattice layer 110. Following this, an AlN layer having a thickness of 70 nm was formed as the connection layer 120. Furthermore, an AlN layer having a thickness of 5 nm was formed as the third layer 132 and an Al_{0.1}Ga_{0.9}N layer having a thickness of 16 nm was formed as the fourth layer 134. The AlN layer having a thickness of 5 nm and the Al_{0.1}Ga_{0.9}N layer provide the second unit layer 136. Here, 75 second unit layers 136 were formed to provide the second superlattice layer 130. After this, a GaN layer having a thickness of 800 nm was formed as the device base layer 142, and an Al_{0.2}Ga_{0.8}N layer having a thickness of 20 nm was formed as the active layer 144. Note that a plurality of types of semiconductor wafers 100 were fabricated with the reaction temperature during the formation of the first superlattice layer 110 being set to various levels. In this way, a plurality of semiconductor wafers 100 that have five different levels of carbon atom concentration, i.e., 1×10¹⁸, 5×10¹⁸, 7×10¹⁸, 1×10¹⁹ and 6×10¹⁹ (in cm⁻³) were fabricated. The average lattice constant of the first superlattice layer 110 is 0.316187 nm and the average lattice constant of the second superlattice layer 130 is 0.316480 nm. The average lattice constant of the connection layer 120 is 0.311200 nm.

### COMPARATIVE EXAMPLES

To be compared against the implementations, the following first to third comparative examples were fabricated.

### First Comparative Example

The connection layer 120 was not provided, the Al ratio of the fourth layer 134 was set to 0.15 so that the average lattice constant of the first superlattice layer 110 was controlled to be the same as the average lattice constant of the second superlattice layer 130, and the other characteristics were set the same as in the first implementation.

### Second Comparative Example

The Al ratio of the fourth layer 134 was set to 0.15 so that the average lattice constant of the first superlattice layer 110 was controlled to be the same as the average lattice constant of the second superlattice layer 130, and the other characteristics were set the same as in the first implementation.

### Third Comparative Example

The connection layer 120 was not provided, and the other characteristics were set the same as in the first implementation.

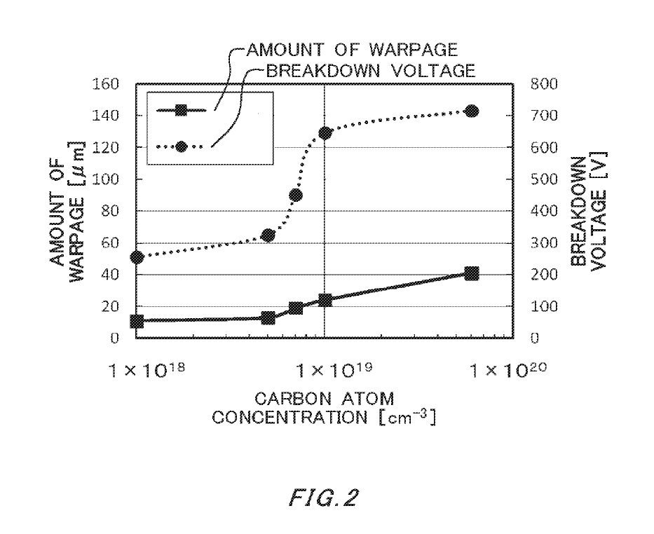

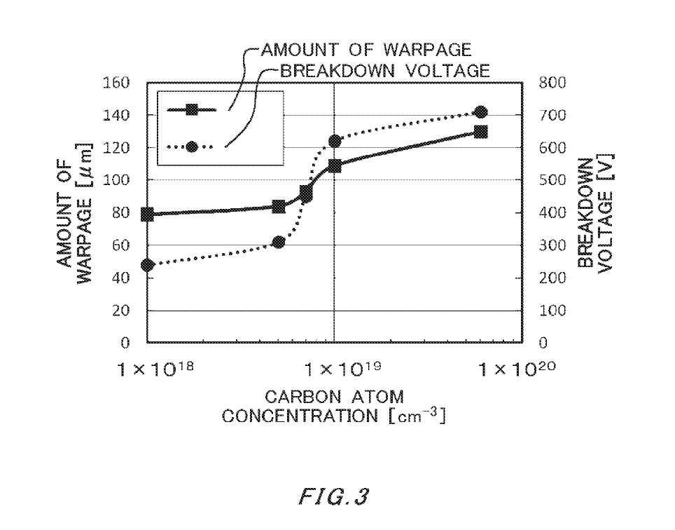

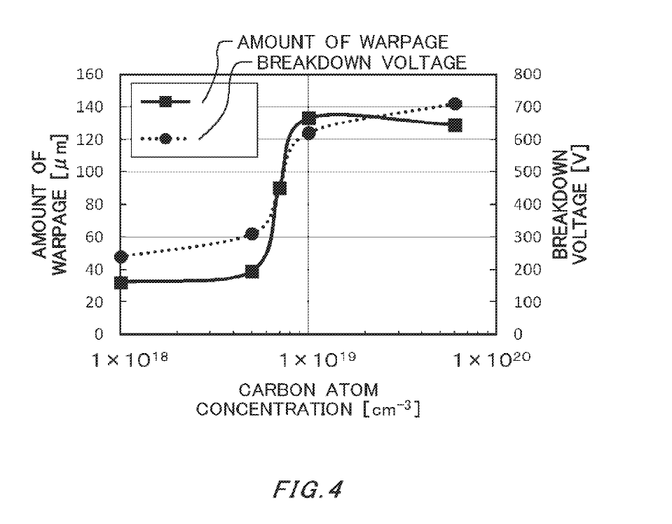

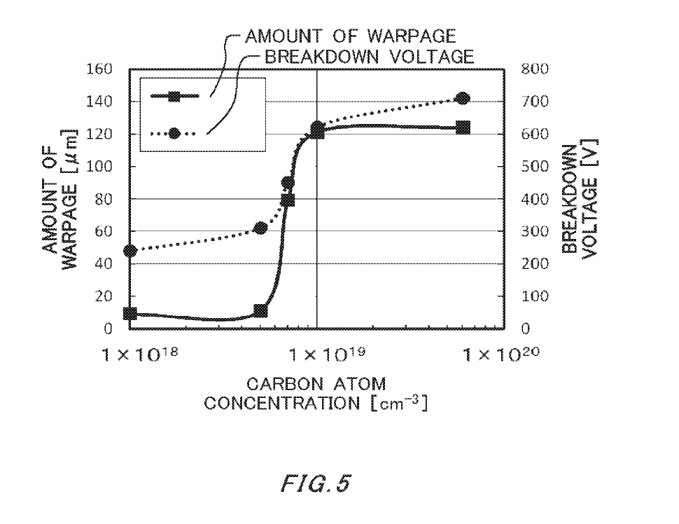

FIG. 2 is a graph showing the amount of warpage and the breakdown voltage in relation to the carbon atom concentration for the semiconductor wafers of the first implementation. FIG. 3 is a graph showing the amount of warpage and the breakdown voltage in relation to the carbon atom concentration for the semiconductor wafers of the first comparative example. FIG. 4 is a graph showing the amount of warpage and the breakdown voltage in relation to the carbon atom concentration for the semiconductor wafers of the second comparative example. FIG. 5 is a graph showing the amount of warpage and the breakdown voltage in relation to the carbon atom concentration for the semiconductor wafer of the third comparative example. The carbon atom concentration means the average concentration measured by SIMS depth analysis. The amount of warpage was evaluated by measuring the height of the respective portions of the wafer by means of laser light. Note that the amount of warpage takes a positive value when measured in the direction in which the middle portion of the wafer is higher than the edge portion of the wafer. To define the breakdown voltage, the current and voltage were measured between the ohmic electrode of 250 μm×200 μm formed on the active layer 144 and the ohmic electrode formed on the entire back plane of the underlying wafer 102. Here, the breakdown voltage was defined as the voltage that is being applied when the current exceeds 1 μA/mm².

The results shown in FIGS. 2 to 5 indicate that the breakdown voltage rises to approximately 700 V in the domain in which the carbon atom concentration exceeds 5×10¹⁸ (cm⁻³). In the first to third comparative examples, however, the amount of warpage exceeds 100 μm in the domain in which the carbon atom concentration is high. In the first implementation, on the other hand, the amount of warpage remains approximately 40 μm or less even if the carbon atom concentration is high. Thus, the amount of warpage can be kept small. Note that, in the domain in which the carbon atom concentration is low and 5×10¹⁸ (cm⁻³) or less, the second and third comparative examples also keep the amount of warpage small to a similar extent as the first implementation. This is believed to be achieved by the effect of the connection layer 120 (the second comparative example) and the effect of the difference in average lattice constant between the first superlattice layer 110 and the second superlattice layer 130 (the third comparative example). However, the advantageous effects achieved by the second and third comparative examples are limited to the domain in which the carbon atom concentration is low and lost in the domain in which the carbon atom concentration is high.

(Second Implementation)

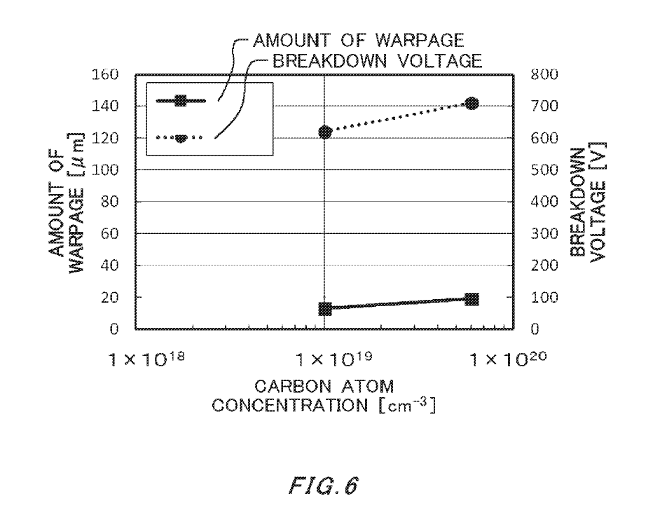

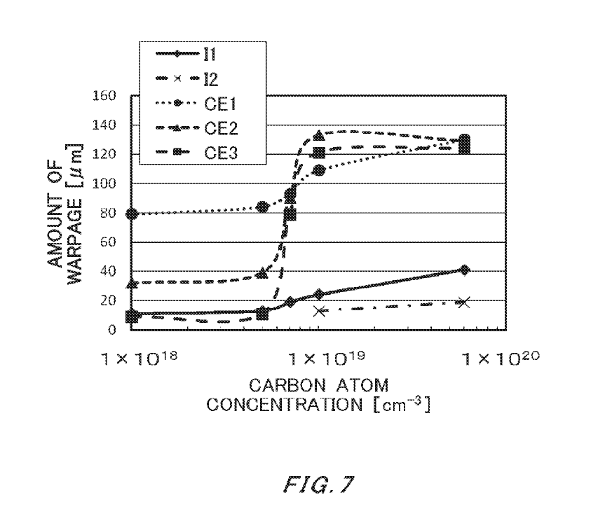

According to a second implementation, a semiconductor wafer was fabricated in the same manner as in the first implementation except that the composition of the connection layer 120 is varied in a continuous manner in the thickness direction from the first superlattice layer 110 to the second superlattice layer 130 from AlN to Al_{0.3}Ga_{0.7}N. Here, the carbon atom concentration was set to two different levels of 1×10¹⁹ and 6×10¹⁹ (in cm⁻³). FIG. 6 is a graph showing the amount of warpage and the breakdown voltage in relation to the carbon atom concentration for the semiconductor wafers of the second implementation. FIG. 7 is provided to easily comprehend the comparison between the first and second implementations. FIG. 7 is a graph showing the amount of warpage in relation to the carbon atom concentration for the semiconductor wafers of the first and second implementations (I1 and I2) and the first to third comparative examples (CE1, CE2 and CE3). The results shown in FIG. 7 indicate that the amount of warpage for the semiconductor wafers of the second implementation is regulated lower not only than the amount of warpage for the semiconductor wafers of the first to third comparative examples, but also than the amount of warpage for the semiconductor wafers of the first implementation.

(Third Implementation)

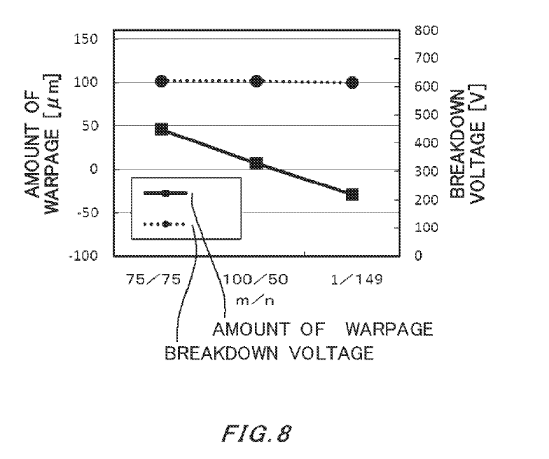

In a third implementation, exemplary semiconductor wafers were fabricated with the numbers n and m being set to various values, where the number n denotes the number of the first unit layers 116 in the first superlattice layer 110 and the number m denotes the number of the second unit layers 136 in the second superlattice layer 130. The semiconductor wafers were fabricated in the same manner as in the first implementation except that the carbon atom concentration was fixed at 1×10¹⁹ (cm⁻³) and the numbers n and m were set at various levels. The numbers n and m were set at three different levels of n/m=75/75, 100/50 and 1/149. FIG. 8 is a graph showing the amount of warpage and the breakdown voltage for the semiconductor wafers of the third implementation. The results shown in FIG. 8 indicate that the amount of warpage can be controlled by varying the numbers n and m.

(Fourth Implementation)

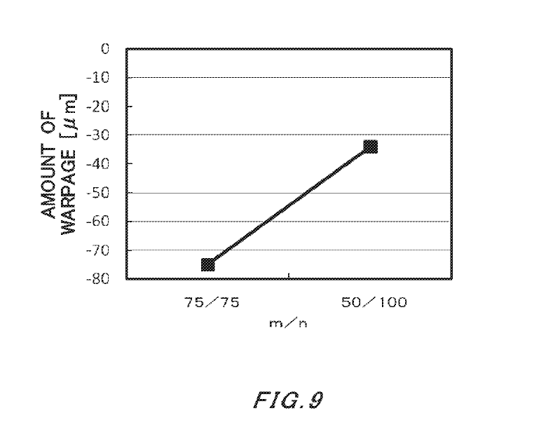

In semiconductor wafers of a fourth implementation, a sapphire wafer was used as the underlying wafer 102. The semiconductor wafers were fabricated in the same manner as in the first implementation except that a sapphire wafer was used as the underlying wafer 102, the carbon atom concentration was fixed to 1×10¹⁹ (cm⁻³) and the numbers n and m were set at various levels. The numbers n and m were set at 2 different levels of n/m=75/75 and 50/100. FIG. 9 is a graph showing the amount of warpage for the semiconductor wafers of the fourth implementation. The results shown in FIG. 9 indicate that the amount of warpage can be controlled by varying the numbers n and m of the unit layers included in the first superlattice layer 110 and the second superlattice layer 130 even when the underlying wafer 102 is a sapphire wafer.

(Fifth Implementation)

In a fifth implementation, exemplary semiconductor wafers were fabricated with the Al ratio of the Alga layer, which is the fourth layer 134, being varied within the range of 0.15 to 0.10. The fifth implementation is the same as the first implementation except that the carbon atom concentration was fixed to 1×10¹⁹ (cm⁻³). The Al ratio was set to six different levels of 0.15, 0.14, 0.13, 0.12, 0.11 and 0.10. The cases where the Al ratio was set to the levels of 0.10 and 0.15 respectively correspond to one of the cases of the first implementation and one of the cases of the second comparative example where the carbon atom concentration was 1×10¹⁹ (cm⁻³). Thus, the semiconductor wafers of the first implementation and the second comparative example for which the carbon atom concentration was set to 1×10¹⁹ (cm⁻³) were respectively used as the semiconductor wafers of the fifth implementation for which the Al ratio was set to the levels of 0.10 and 0.15. When the Al ratio is set to 0.15, 0.14, 0.13, 0.12, 0.11 and 0.10, the average lattice constant of the second superlattice layer 130 takes values of 0.316187, 0.316245, 0.316304, 0.316363, 0.316421 and 0.316480 (in nm). Since the average lattice constant of the first superlattice layer 110 is 0.316187 nm, the difference in average lattice constant (the average lattice constant of the second superlattice layer 130—the average lattice constant of the first superlattice layer 110) is 0.000000, 0.000059, 0.000117, 0.000176, 0.000235 and 0.000293 (in nm) when the Al ratio is set to 0.15, 0.14, 0.13, 0.12, 0.11 and 0.10.

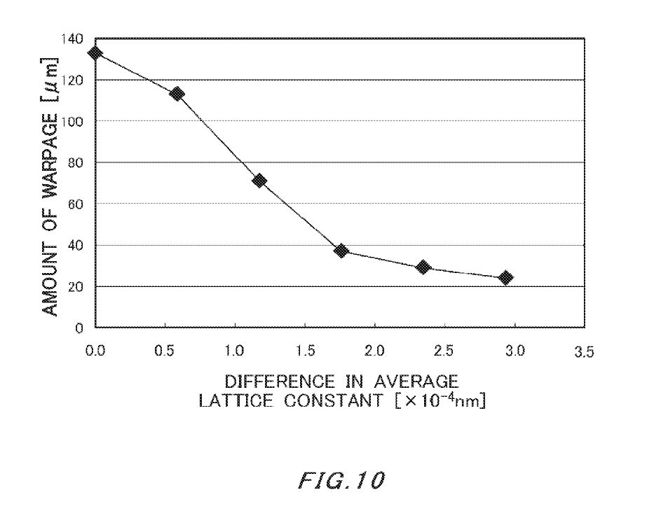

FIG. 10 is a graph showing the amount of warpage in relation to the difference in average lattice constant for the semiconductor wafers of the fifth implementation. The results shown in FIG. 10 indicate that the amount of warpage decreases as the difference in average lattice constant increases. The results also indicate that, when the average lattice constant of the second superlattice layer 130 becomes even slightly larger than the average lattice constant of the first superlattice layer 110 (when the difference in average lattice constant becomes larger), the amount of warpage changes and the change in the value of the amount of warpage is sensitive to the change in the difference in average lattice constant. This demonstrates that the above-described mechanism allowing the amount of warpage of the semiconductor wafer to be controlled small regardless of introduction of a high concentration of impurity atoms effectively works to control the amount of warpage as a result of successful mutual transfer of stress between the first superlattice layer 110 and the second superlattice layer 130.

When compared against the increase in the difference in average lattice constant, the decrease in the amount of warpage tends to be saturated after the difference in average lattice constant exceeds substantially 0.00017 nm. This probably indicates such a tendency that the stress increases as a result of the increase in the difference in average lattice constant and lattice relaxation resultantly starts to increase at the crystal interfaces. The increase in lattice relaxation results in absorption of the stress, which degrades the controllability of the amount of warpage. Accordingly, it is believed that an upper limit is imposed on the range of the difference in average lattice constant to ensure the controllability of the amount of warpage. Note that the facts that the amount of warpage can be precisely controlled by regulating the difference in average lattice constant and that the drop in the amount of warpage tends to be saturated once the difference in average lattice constant becomes large agree with the mechanism described earlier and infer the effectiveness of the mechanism among other facts.

### EXPLANATION OF REFERENCES

100 . . . semiconductor wafer, 102 . . . underlying wafer, 104 . . . buffering layer, 110 . . . first superlattice layer, 112 . . . first layer, 114 . . . second layer, 116 . . . first unit layer, 120 . . . connection layer, 130 . . . second superlattice layer, 132 . . . third layer, 134 . . . fourth layer, 136 . . . second unit layer, 140 . . . nitride semiconductor crystal layer, 142 . . . device base layer, 144 . . . active layer

What is claimed is:

1. A semiconductor wafer comprising an underlying wafer, a first superlattice layer, a connection layer, a second superlattice layer and a nitride semiconductor crystal layer, wherein
the underlying wafer, the first superlattice layer, the connection layer, the second superlattice layer and the nitride semiconductor crystal layer are positioned in an order of the underlying wafer, the first superlattice layer, the connection layer, the second superlattice layer and the nitride semiconductor crystal layer,
the first superlattice layer includes a plurality of first unit layers each of which is made up by a first layer and a second layer,
the second superlattice layer includes a plurality of second unit layers each of which is made up by a third layer and a fourth layer,
the first layer is made of Alₓ₁Ga₁₋ₓ₁N (0<x1≦1),
the second layer is made of Al_{y1}Ga_{1-y1}N (0≦y1<1, x1>y1),
the third layer is made of Alₓ₂Ga₁₋ₓ₂N (0<x2≦1),
the fourth layer is made of Al_{y2}Ga_{1-y2}N (0≦y2<1, x2>y2),
an average lattice constant of the first superlattice layer is different from an average lattice constant of the second superlattice layer,
one or more layers selected from the first superlattice layer and the second superlattice layer contain impurity atoms that improve a breakdown voltage and that have a concentration higher than 7×10¹⁸ [atoms/cm³].

2. The semiconductor wafer of claim 1, wherein
the impurity atoms are one or more species selected from the group consist of C atoms, Fe atoms, Mn atoms, Mg atoms, V atoms, Cr atoms, Be atoms and B atoms.

3. The semiconductor wafer of claim 2, wherein
the impurity atoms are C atoms or Fe atoms.

4. The semiconductor wafer of claim 1, wherein
the connection layer is a crystal layer in contact with the first superlattice layer and the second superlattice layer.

5. The semiconductor wafer of claim 1, wherein
a composition of the connection layer changes in a continuous manner in a thickness direction of the connection layer from the first superlattice layer to the second superlattice layer.

6. The semiconductor wafer of claim 1, wherein
a composition of the connection layer changes in a stepwise manner in a thickness direction of the connection layer from the first superlattice layer to the second superlattice layer.

7. The semiconductor wafer of claim 1, wherein
the connection layer is made of Al_{z}Ga_{1-z}N (0≦z≦1).

8. The semiconductor wafer of claim 1, wherein
a thickness of the connection layer is larger than a thickness of any of the first layer, the second layer, the third layer and the fourth layer.

9. The semiconductor wafer of claim 1, wherein
an average lattice constant of the connection layer is smaller than an average lattice constant of any of the first superlattice layer and the second superlattice layer.

10. The semiconductor wafer of claim 1, wherein
the first superlattice layer includes 1 to 200 first unit layers each of which is made up by the first layer and the second layer.

11. The semiconductor wafer of claim 1, wherein
the second superlattice layer includes 1 to 200 second unit layers each of which is made up by the third layer and the fourth layer.

12. A method of producing the semiconductor wafer of claim 1, the method comprising:
forming the first superlattice layer by forming the first unit layer, which is made up by the first layer and the second layer, n times;
forming the connection layer;
forming the second superlattice layer by forming the second unit layer, which is made up by the third layer and the fourth layer, m times; and
forming the nitride semiconductor crystal layer, wherein
during one or more formations selected from the formation of the first superlattice layer and the formation of the second superlattice layer, the one or more of the first superlattice layer and the second superlattice layer are formed so as to contain impurity atoms that improve a breakdown voltage of the one or more of the first superlattice layer and the second superlattice layer and that have a concentration higher than 7×10¹⁸ [atoms/cm³].

13. The method of claim 12, wherein
depending on a composition and a thickness of the nitride semiconductor crystal layer, one or more parameters selected from (i) a composition of each of the first to fourth layers, (ii) a thickness of each of the first to fourth layers, (iii) the number n of the unit layers included in the first superlattice layer and (iv) the number m of the unit layers included in the second superlattice layer are adjusted so that warpage of the semiconductor wafer measured at a surface of the nitride semiconductor crystal layer is 50 μm or less.

14. The method of claim 13, wherein
depending on the composition and the thickness of the nitride semiconductor crystal layer, the number n of the unit layers included in the first superlattice layer and the number m of the unit layers included in the second superlattice layer are adjusted so that the warpage of the semiconductor wafer measured at the surface of the nitride semiconductor crystal layer is 50 μm or less.
